(19) United States
(12) Patent Application Publication
(10) Pub. No.: US 2023/0013572 A1
(43) Pub. Date: Jan. 19, 2023

(54) DISPLAY DEVICE

(71) Applicant: Japan Display Inc., Tokyo (JP)

(72) Inventors: Shuichi OSAWA, Tokyo (JP); Yoshikatsu IMAZEKI, Tokyo (JP); Yoichi KAMIJO, Tokyo (JP); Koichi MIYASAKA, Tokyo (JP); Yoshifumi KAMEI, Tokyo (JP)

(21) Appl. No.: 17/950,176

(22) Filed: Sep. 22, 2022

Related U.S. Application Data
(63) Continuation of application No. PCT/JP2021/008140, filed on Mar. 3, 2021.

(30) Foreign Application Priority Data
Mar. 26, 2020 (JP) 2020-056213

(51) Int. Cl. H01L 33/38; H01L 33/62; H01L 25/075

(52) U.S. Cl. CPC H01L 33/382; H01L 33/62; H01L 25/0753

(57) ABSTRACT

A display device includes a first substrate having a first surface and a second surface opposite to the first surface, a first light-emitting layer including a first polymer and an ionic liquid on the second surface, a first electrode provided on a first side surface of the first light-emitting layer, a second electrode provided on a second side surface of the first light-emitting layer opposite to the first side surface of the first light-emitting layer, and a second substrate in contact with the first light-emitting layer opposite to the first substrate.

### CROSS-REFERENCE TO RELATED APPLICATIONS

This application is a Continuation of International Patent Application No. PCT/JP2021/008140, filed on Mar. 3, 2021, which claims the benefit of priority to Japanese Patent Application No. 2020-056213, filed on Mar. 26, 2020, the entire contents of which are incorporated herein by reference.

### FIELD

One embodiment of the present invention relates to a display device including a light-emitting Electrochemical Cell (LEC) and a method of manufacturing the display device.

### BACKGROUND

In recent years, a light-emitting electrochemical cell has attracted attention as a light-emitting element. The light-emitting electrochemical cell has a structure in which a first electrode, a second electrode, a light-emitting layer including a light-emitting polymer and an ionic liquid are stacked, and the light-emitting layer is sandwiched between the first electrode and the second electrode. The light-emitting layer of the light-emitting electrochemical cell contains both electrons and ions and emits light by spontaneously forming a p-i-n bond by applying a voltage between the first electrode and the second electrode (see Japanese laid-open patent publication No. 2011-103234 and Japanese laid-open patent publication No. 2000-67601).

### SUMMARY

A display device according to one embodiment of the present invention includes a first substrate having a first surface and a second surface opposite to the first surface, a first light-emitting layer including a first polymer and an ionic liquid on the second surface, a first electrode provided on a first side surface of the first light-emitting layer, a second electrode provided on a second side surface of the first light-emitting layer opposite to the first side surface of the first light-emitting layer, and a second substrate in contact with the first light-emitting layer opposite to the first substrate.

### BRIEF DESCRIPTION OF DRAWINGS

FIG. 1 is an exploded view of a display device according to one embodiment of the present invention.

FIG. 2 is a cross-sectional view when a display device shown in FIG. 1 is sectioned along a line A1-A2.

FIG. 3 is a plan view showing an outline of an element formation layer.

FIG. 4 is a layout of a light-emitting electrochemical cell according to one embodiment of the present invention.

FIG. 5 is a cross-sectional view when a light-emitting electrochemical cell shown in FIG. 4 is sectioned along a line B1-B2.

FIG. 6A is a cross-sectional view illustrating a method of manufacturing a display device according to one embodiment of the present invention.

FIG. 6B is a cross-sectional view illustrating a method of manufacturing a display device according to one embodiment of the present invention.

FIG. 7A is a cross-sectional view illustrating a method of manufacturing a display device according to one embodiment of the present invention.

FIG. 7B is a cross-sectional view illustrating a method of manufacturing a display device according to one embodiment of the present invention.

FIG. 8A is a cross-sectional view illustrating a method of manufacturing a display device according to one embodiment of the present invention.

FIG. 8B is a cross-sectional view illustrating a method of manufacturing a display device according to one embodiment of the present invention.

FIG. 9 is a cross-sectional view when a display device is cut across a plurality of light-emitting electrochemical cells.

FIG. 10 is a layout of a light-emitting electrochemical cell according to one embodiment of the present invention.

FIG. 11 is a cross-sectional view when the layout of a light-emitting electrochemical cell shown in FIG. 10 is sectioned along a line C1-C2.

FIG. 12A is a cross-sectional view illustrating a method of manufacturing a display device according to one embodiment of the present invention.

FIG. 12B is a cross-sectional view illustrating a method of manufacturing a display device according to one embodiment of the present invention.

FIG. 13A is a cross-sectional view illustrating a method of manufacturing a display device according to one embodiment of the present invention.

FIG. 13B is a cross-sectional view illustrating a method of manufacturing a display device according to one embodiment of the present invention.

FIG. 14 is a cross-sectional view illustrating a method of manufacturing a display device according to one embodiment of the present invention.

FIG. 15 is a layout of a light-emitting electrochemical cell according to one embodiment of the present invention.

FIG. 16 is a layout of a light-emitting electrochemical cell according to one embodiment of the present invention.

FIG. 17 is a layout of a light-emitting electrochemical cell according to one embodiment of the present invention.

FIG. 18 is a cross-sectional view of a light-emitting electrochemical cell and an element formation layer according to one embodiment of the present invention.

### DESCRIPTION OF EMBODIMENTS

Hereinafter, embodiments of the present invention will be described with reference to the drawings and the like. However, the present invention can be implemented in many different aspects and should not be construed as being limited to the description of the embodiments exemplified below. Although the width, thickness, shape, and the like of each part are schematically represented in comparison with the actual embodiments in order to clarify the description, the drawings are merely examples and do not limit the interpretation of the present invention. In addition, in the present specification and the drawings, elements similar to those described above with respect to the above-described figures are denoted by the same symbols (or symbols denoted by A, B, and the like) and a detailed description thereof may be omitted as appropriate. Furthermore, the letters “first” and “second” with respect to each element are convenient signs used to distinguish each element, and do not have any further meaning unless otherwise specified.

In the present specification, when a member or area is described as being “above (or below)” another member or area, this includes not only the case where it is directly above (or directly below) the other member or area but also the case where it is above (or below) the other member or area, i.e., it includes the case where other components are included between the above (or below) the other members or areas. Also, in the following explanation, unless otherwise specified, in a cross-sectional view, a side on which a light-emitting electrochemical cell 120 is provided with respect to a first substrate is referred to as “upper” or “above”, a side viewed from “upper” or “above” is referred to as “upper surface” or “upper surface side”, and the opposite side is referred to as “lower”, “below”, “lower surface” or “lower surface side”.

### First Embodiment

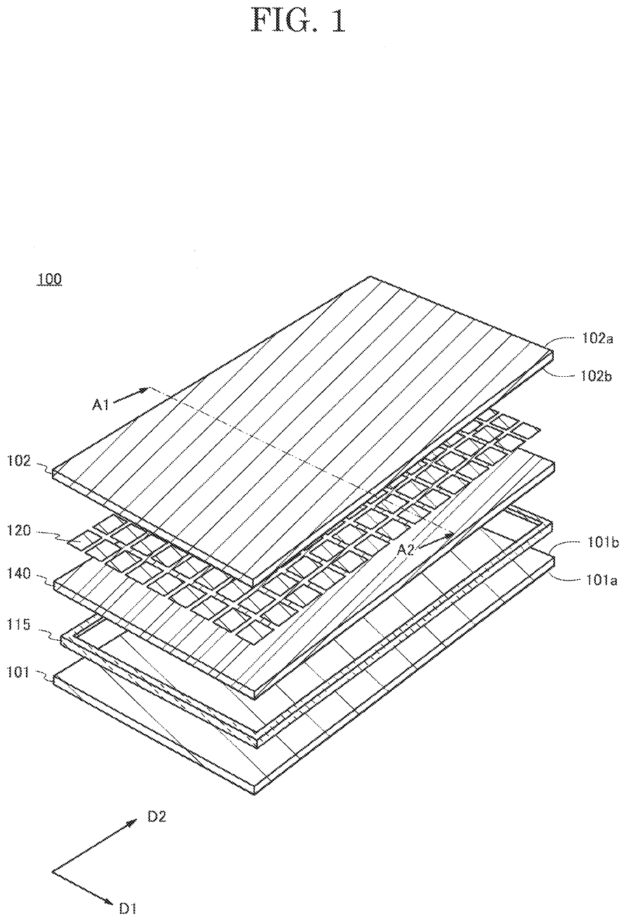

A display device 100 according to one embodiment of the present invention will be described with reference to FIG. 1 to FIG. 8B.

### <Display Device Structure>

First, a structure of the display device 100 according to one embodiment of the present invention will be described while referring to FIG. 1 to FIG. 8B. FIG. 1 is an exploded view of the display device 100 according to one embodiment of the present invention. The display device 100 includes a first substrate 101, an element formation layer 140, a light-emitting electrochemical cell 120, and a second substrate 102.

The element formation layer 140 is provided on the first substrate 101. A pixel circuit including a switching element for controlling the light-emitting electrochemical cell 120 is arranged in a matrix in the element formation layer 140.

The light-emitting electrochemical cell 120 is arranged in a matrix on the element formation layer 140. In addition, the light-emitting electrochemical cell 120 is electrically connected to the switching element and is controlled by turning the switching element on/off. The light-emitting electrochemical cell 120 has a structure in which a light-emitting layer including a light-emitting polymer and an ionic liquid is sandwiched between a first electrode and a second electrode. The light-emitting layer includes both electrons and ions and the light-emitting layer emits light by spontaneously forming a p-i-n bond by applying a voltage between the first electrode and the second electrode. Also, the ionic liquid refers to an organic salt that is liquid at room temperature. A structure of the light-emitting electrochemical cell 120 is described in detail later.

The second substrate 102 is provided on the light-emitting electrochemical cell 120. The first substrate 101 and the second substrate 102 are bonded via an adhesive material 115.

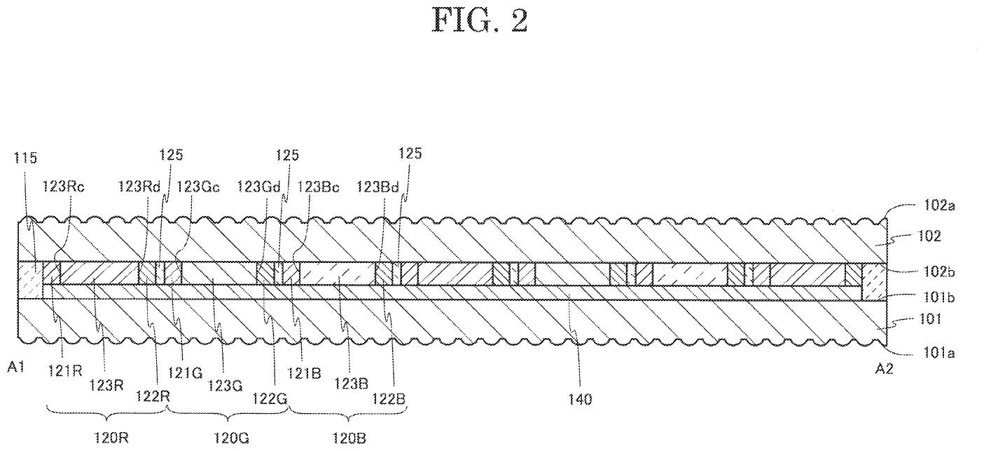

FIG. 2 is a cross-sectional view when the display device 100 shown in FIG. 1 is sectioned along a line A1-A2.

For example, a glass substrate or a plastic substrate is used as the first substrate 101 and the second substrate 102. For example, an organic resin such as acryl, polyimide, polyethylene terephthalate, and polyethylene naphthalate is used as the plastic substrate. The display device 100 that can be bent or curved can be formed as the first substrate 101 and the second substrate 102 using a plastic substrate having flexibility.

The first substrate 101 has a first surface 101a and a second surface 101b facing the first surface 101a. In addition, the second substrate 102 has a first surface 102a and a second surface 102b facing the first surface 102a. The first surface 102a of the second substrate 102 is a surface from which light emitted from a light-emitting layer 123 is emitted, and the first surface 102a preferably has a light diffusion effect. For example, the first surface 102a preferably has a minute unevenness formed by an antiglare treatment. In addition, in the case where the light emitted from the light-emitting layer 123 is also emitted from the first surface 101a of the first substrate 101, the first surface 101a preferably has a light diffusion effect. The first surface 101a preferably has a minute unevenness formed by an antiglare treatment. The light emission of the light-emitting electrochemical cell 120 may be emitted from the first surface 102a side of the second substrate 102 or may be emitted from the first surface 101a side of the first substrate 101. In addition, the light emission of the light-emitting electrochemical cell 120 may be emitted from both the first surface 102a of the second substrate 102 and the first surface 101a of the first substrate 101.

The element formation layer 140 is provided on the first surface 101a of the first substrate 101, and the light-emitting electrochemical cell 120 is provided on the element formation layer 140. In the present embodiment, light-emitting electrochemical cells 120R, 120G, and 120B having different emission spectrum peaks are used as the light-emitting electrochemical cell 120. In the present embodiment, the light-emitting electrochemical cell 120R emits red, the light-emitting electrochemical cell 120G emits green, and the light-emitting electrochemical cell 1208 emits blue. In the following explanation, when the light-emitting electrochemical cells 120R, 120G, and 120B are not distinguished, they are simply referred to as the light-emitting electrochemical cell 120. In addition, the same applies to each component of the light-emitting electrochemical cells 120R, 120G, and 120B.

The light-emitting electrochemical cell 120R has a structure in which a light-emitting layer 123R including a light-emitting polymer and an ionic liquid is sandwiched between a first electrode 121R and a second electrode 122R. That is, a side surface 123Rc of the light-emitting layer 123R is in contact with the first electrode 121R, and a side surface 123Rd is in contact with the second electrode 122R. Therefore, the light-emitting layer emits light by spontaneously forming a p-i-n bond by applying a voltage between the first electrode 121 and the second electrode 122. Similarly, the light-emitting electrochemical cell 120G has a structure in which a light-emitting layer 123G including a light-emitting polymer and an ionic liquid is sandwiched between a first electrode 121G and a second electrode 122G. A first side surface 123Gc of the light-emitting layer 123G is in contact with the first electrode 121G, and a second side surface 123Gd is in contact with the second electrode 122G. The light-emitting electrochemical cell 120B has a structure in which a light-emitting layer 123B including a light-emitting polymer and an ionic liquid is sandwiched between a first electrode 121B and a second electrode 122B. The first side surface 123Bc of the light-emitting layer 123B is in contact with the first electrode 121B, and the second side surface 123Bd is in contact with the second electrode 122B.

The first electrode 121 and the second electrode 122 include at least one of an oxide conductive layer and a metal conductive layer. For example, an indium-oxide-based transparent conductive layer (for example, ITO) or a zinc-oxide-based transparent conductive layer (for example, IZO, ZnO) is used as the oxide conductive layer. In addition, an MgAg thin film may be used as the conductive layer having light transmittance instead of the oxide conductive layer. For example, a single layer or a stacked layer of copper, titanium, molybdenum, tantalum, tungsten, or aluminum is used as the conductive layer. In the present embodiment, the case where the oxide conductive layer is used as the first electrode 121 and the second electrode 122 will be described. In addition, in the present embodiment, although the hatching of the first electrode 121 and the hatching of the second electrode 122 are illustrated by different hatching, they have the same conductive material when the first electrode 121 and the second electrode 122 are formed of the same conductive film. Also, the first electrode 121 and the second electrode 122 may be formed of different conductive films. In this case, the first electrode 121 and the second electrode 122 may have different conductive materials. The thickness of each of the first electrode 121 and the second electrode 122 is, for example, 50 nm or more and 150 nm or less.

The light-emitting layer 123 includes a light-emitting polymer and an ionic liquid. The light-emitting layer 123R, the light-emitting layer 123G, and the light-emitting layer 1238 have different light-emitting polymers. When the thickness of the light-emitting layer 123 is increased, an electric field is less likely to be applied between the first electrode 121 and the second electrode 122, and when the thickness is decreased, the first electrode 121 and the second electrode 122 are shorted. Therefore, the thickness of each of the light-emitting layers 123R, 123G, and 123B is preferred to be 50 nm or more and 150 nm or less, for example. The thickness of the light-emitting layer 123 may be appropriately set within the above-described range according to the thicknesses of the first electrode 121 and the second electrode 122.

An insulating layer 125 is provided between the second electrode 122R and the first electrode 121G. The insulating layer 125 electrically insulates the second electrode 122R and the first electrode 121G. The insulating layer 125 may have light transmittance and may be an inorganic material such as silicon oxide or silicon nitride, or an organic material such as polyimide, polyamide, acryl, or epoxy. A non-light transmittance film such as a metal film may be arranged on the side surface of the insulating layer 125. According to this structure, it is possible to suppress unintentional mixing of lights of different colors emitted from the adjacent light-emitting layer 123R, the light-emitting layer 123G, and the light-emitting layer 123B.

The adhesive material 115 is provided so as to surround peripheral edges of the first substrate 101 and the second substrate 102. As a result, the first substrate 101 and the second substrate 102 are bonded. Since the light-emitting layer 123 deteriorates by moisture, the adhesion between the first substrate 101 and the second substrate 102 is preferably high.

Although FIG. 2 shows the second surface 102b of the second substrate 102 and the light-emitting electrochemical cell 120 are illustrated as being in contact with each other, the structure is not limited thereto. An insulating film may be provided between the second surface 102b of the second substrate 102 and the light-emitting electrochemical cell 120. The insulating film is provided on a side of the second surface 102b of the second substrate 102. The insulating film may be an inorganic material such as silicon oxide or silicon nitride, or an organic material such as polyimide, polyamide, acryl, or epoxy.

According to conventional light-emitting electrochemical cells, a total thickness of the light-emitting electrochemical cells was increased because the light-emitting electrochemical cells were formed by stacking the first electrode, the light-emitting layer, and the second electrode. In addition, since a metal conductive layer such as aluminum is used for at least one of the stacked first electrode or the second electrode, it is difficult to emit the light emission of the light-emitting electrochemical cell from both the upper substrate and the lower substrate.

The display device 100 according to one embodiment of the present invention, the light-emitting electrochemical cell 120 includes the first electrode 121, the second electrode 122, and the light-emitting layer 123 on the element formation layer 140, and they are not stacked. The thicknesses of the first electrode 121, the second electrode 122, and the light-emitting layer 123 are substantially the same. As a result, the thickness of the light-emitting electrochemical cell 120 can be made smaller than when the first electrode 121, the second electrode 122, and the light-emitting layer 123 are stacked in this order. As a result, the total thickness of the display device 100 can be reduced. In addition, since the first electrode 121 and the second electrode 122 are not stacked on the light-emitting layer 123, the light emission from the light-emitting layer 123 is not blocked by the first electrode 121 and the second electrode 122 even if the metal conductive layer is used for the first electrode 121 and the second electrode 122. Therefore, the light emitted from the light-emitting layer 123 can be emitted from both the first substrate 101 side and the second substrate 102 side.

### <Plan View of Element Formation Layer>

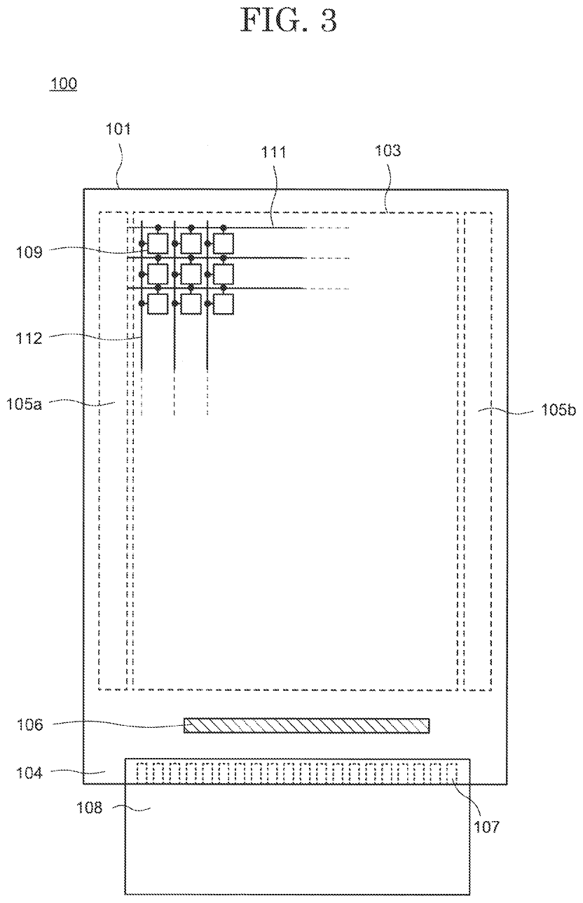

FIG. 3 is a plan view showing an outline of the element formation layer 140. As shown in FIG. 3, a display area 103 is provided on the first substrate 101, and a peripheral area 104 is provided around the display area 103. A plurality of pixel circuits 109 is arranged in a matrix in the display area 103. Each of the pixel circuits 109 arranged in a matrix overlap each of the light-emitting electrochemical cells 120. Although not shown in FIG. 3, the switching element included in the pixel circuit 109 is electrically connected to the light-emitting electrochemical cell 120. The light emission of the light-emitting electrochemical cell 120 is controlled by the switching element.

In addition, scan line drive circuits 105a and 105b are provided in the peripheral area 104 so as to sandwich the display area 103, and a plurality of terminals 107 is provided at an end portion (end portion of the first substrate 101) in the peripheral area 104. A driver IC 106 is provided between the plurality of terminals 107 and the display area 103. In addition, the plurality of terminals 107 is connected to a flexible printed circuit board 108.

The scan line drive circuits 105a and 105b are connected to a gate wiring 111 which is connected to the pixel circuit 109. The driver IC 106 is connected to a data wiring 112 which is connected to the pixel circuit 109. Although FIG. 3 shows an example in which a signal line drive circuit is incorporated in the driver IC is shown, the signal line drive circuit is provided on the first substrate 101 separately from the driver IC 106. The driver IC 106 may be arranged on the first substrate 101 in the form of an IC chip or may be arranged on the flexible printed circuit board 108.

In addition, although not shown, the pixel circuit 109 has a switching element, a gate of a switching element 130 is connected to the gate wiring 111, and a source or drain of the switching element 130 is connected to the data wiring 112.

### <Layout of Light-Emitting Electrochemical Cells>

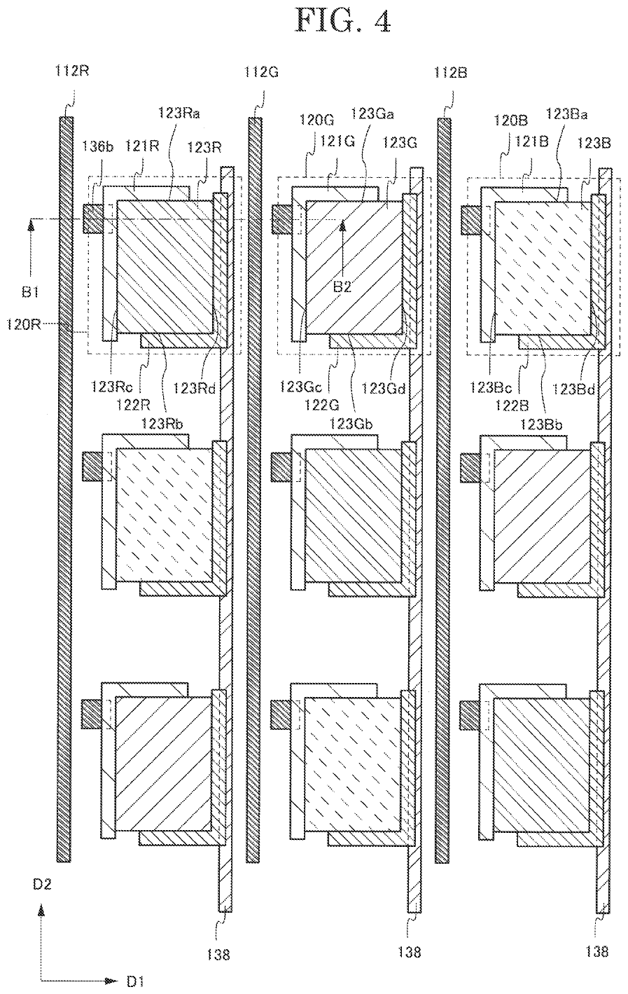

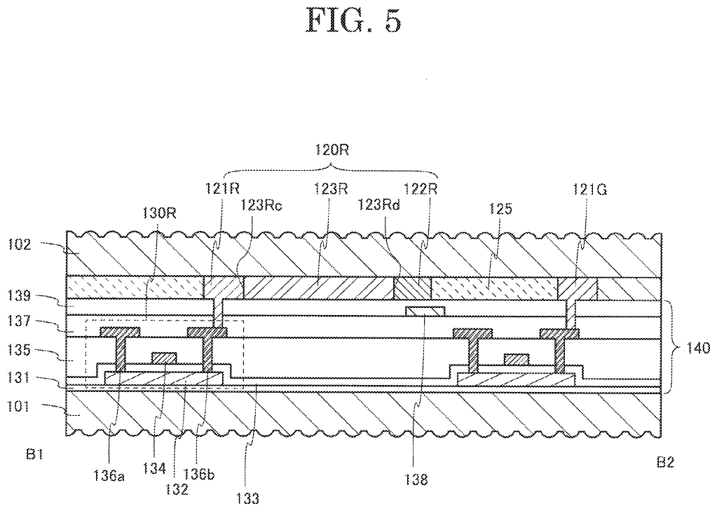

Next, the pixel circuit 109 and the light-emitting electrochemical cell 120 included in the display device 100 will be described with reference to FIG. 4 and FIG. 5. FIG. 4 is a layout of the light-emitting electrochemical cell 120. FIG. 4 shows not only the light-emitting electrochemical cell 120, but also data wirings 112R, 112G, and 112B, and common wirings 138R, 138G, and 138B formed in the element formation layer 140. Although not shown, the common wirings 138R, 138G, and 138B are electrically connected in the peripheral area 104.

As shown in FIG. 4, the first electrode 121 has a straight portion extending at least along a first direction D1. Specifically, the first electrode 121 has a straight portion extending along the first direction D1 and a straight portion bent in a second direction D2 intersecting the first direction D1. The second electrode 122 has a straight portion extending at least along the first direction D1. Specifically, the second electrode 122 has a straight portion extending along the first direction D1 and a straight portion bent in the second direction D2 intersecting the first direction D1. That is, the first electrode 121 has a shape opposite to an L-shape (the same shape as when the line-symmetrical shape of the L-shape is rotated 180° to the left with respect to the rotation center), and the second electrode 122 has an L-shape (the line-symmetrical shape of the L-shape). The first electrode 121 and the second electrode 122 face each other, and the light-emitting layer 123 is provided in an area surrounded by the first electrode 121 and the second electrode 122.

A side surface 123Ra and a side surface 123Rb of the light-emitting layer 123R face each other, and the side surface 123Rc and the side surface 123Rd face each other. The side surface 123Ra and the side surface 123Rc of the light-emitting layer 123R are in contact with the first electrode 121R, and the side surface 123Rb and the side surface 123Rd of the light-emitting layer 123R are in contact with the second electrode 122R. Therefore, the light-emitting layer 123R can be made to emit light by applying a voltage between the first electrode 121 in contact with the side surface 123Ra and the second electrode 122 in contact with the side surface 123Rb, and between the first electrode 121 in contact with the side surface 123Rc and the second electrode 122 in contact with the side surface 123Rd.

The first electrode 121R is electrically connected to the data wiring 112R, and the second electrode 122R is electrically connected to the common wiring 138. The first electrode 121G is electrically connected to the data wiring 112G, and the second electrode 122G is electrically connected to the common wiring 138. The first electrode 121B is electrically connected to the data wiring 112B, and the second electrode 122B is electrically connected to the common wiring 138. The light-emitting electrochemical cell 120 controls the emission intensity of the light-emitting layer 123 by applying a voltage corresponding to the signal input to the data wiring 112 to the first electrode 121 and applying the voltage applied to the common wiring 138 to the second electrode 122.

FIG. 5 is a cross-sectional view along a line B1-B2 of the layout of the light-emitting electrochemical cell shown in FIG. 4. In FIG. 5, a detailed structure of the element formation layer 140 and the light-emitting electrochemical cell 120 will be described.

Switching elements 130R and 130G are provided on the first surface 101a of the first substrate 101 via an under layer insulating film 131. Specifically, the switching elements 130R and 130G are transistors. For example, the switching element 130R includes a semiconductor layer 132, a gate insulating film 133, a gate electrode 134, an interlayer insulating film 135, and a source electrode or drain electrode 136a, 136b. Also, the under layer insulating film 131 is provided to prevent impurities from entering the semiconductor layer 132 from the first substrate 101. The semiconductor layer 132 is provided on the under layer insulating film 131, the gate insulating film 133 is provided on the semiconductor layer 132, and the gate electrode 134 is provided to overlap the semiconductor layer 132 via the gate insulating film. The interlayer insulating film 135 is provided to cover the gate electrode 134, and the source electrode or drain electrode 136a, 136b is provided on the interlayer insulating film 135. The source electrode or drain electrode 136a, 136b is connected to the semiconductor layer 132 via contact holes formed in the interlayer insulating film 135. The source electrode or drain electrode 136a is a part of the data wiring 112.

An interlayer insulating film 137 is provided on the interlayer insulating film 135 and the source electrode or drain electrode 136a, 136b, and the common wiring 138 is provided on the interlayer insulating film 137. An insulating film 139 is provided on the interlayer insulating film 137 and the common wiring 138.

Amorphous silicon, polysilicon, or an oxide semiconductor can be used as the semiconductor layer 132. In addition, copper, titanium, molybdenum, tantalum, tungsten, and aluminum can be used as the gate electrode 134, the source electrode or drain electrode 136a, 136b, and the common wiring 138 in a single layer or stacked layer. In addition, an inorganic material such as silicon oxide or silicon nitride can be used as the under layer insulating film 131, the gate insulating film 133, the interlayer insulating film 135, and the interlayer insulating film 137. In addition, the insulating film 139 is preferred to have a planarization function, and an organic material such as polyimide, polyamide, acryl, or epoxy can be used as the insulating film 139.

The first electrode 121R, the second electrode 122R, and the light-emitting layer 123 are provided on the insulating film 139 as the light-emitting electrochemical cell 120R. The first electrode 121R is electrically connected to the source electrode or drain electrode 136b via a contact hole formed in the interlayer insulating film 137 and the insulating film 139. Although not shown in FIG. 5, the second electrode 122R is electrically connected to the common wiring 138 via the contact hole formed in the insulating film 139. In addition, the insulating layer 125 is provided between the second electrode 122R and the first electrode 121G.

### <Method of Manufacturing Display Device>

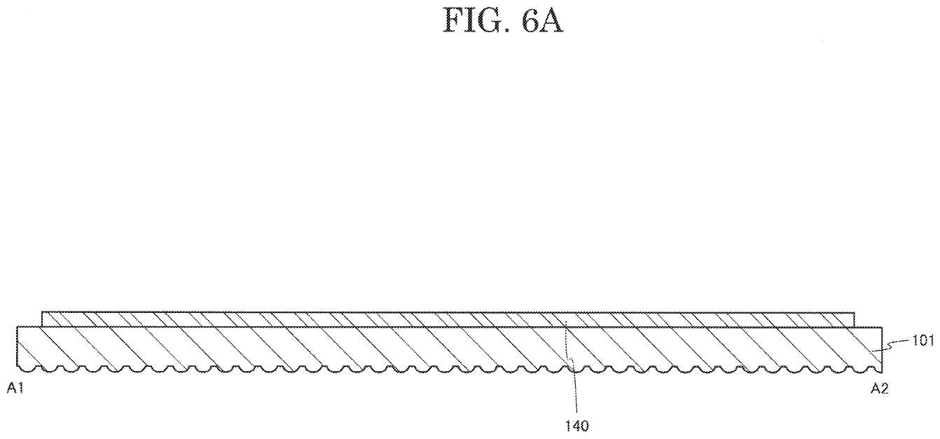

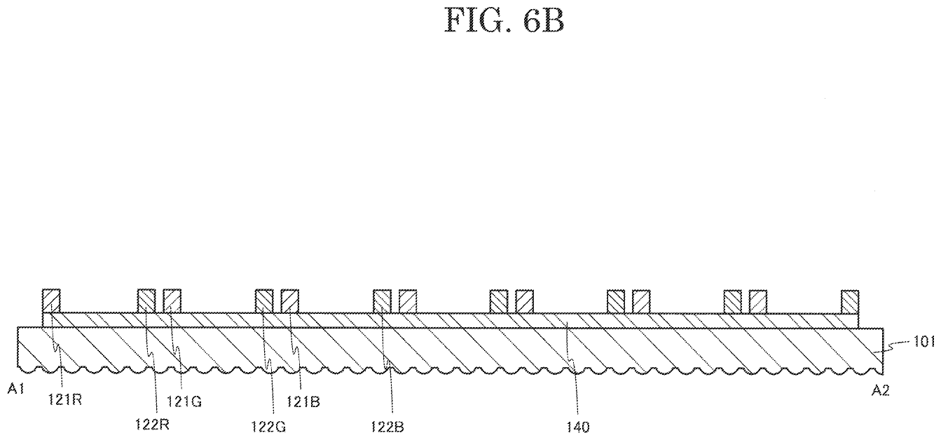

Next, a method of manufacturing the display device 100 according to one embodiment of the present invention will be described while referring to FIG. 6A to FIG. 8B.

FIG. 6A is a diagram illustrating the process of forming the element formation layer 140 on the first substrate 101. The first substrate 101 has the first surface 101a and the second surface 101b facing the first surface 101a. The first surface 101a of the first substrate 101 is subjected to an antiglare treatment. In addition, the thickness of the display device 100 can be reduced by setting the thickness of the first substrate 101 to 0.1 mm to 0.3 mm. Also, in the case where a diffuser or a reflector is separately provided on the first surface 101a side, the antiglare treatment may not be performed on the first surface 101a. The element formation layer 140 is formed on the second surface 101b of the first substrate 101. The under layer insulating film 131, the switching element 130, the interlayer insulating film 137 on the switching element 130, the common wiring 138, and the insulating film 139 included in the element formation layer 140 are formed using a known method.

FIG. 6B is a diagram illustrating a process of forming the first electrodes 121R, 121G, and 121B and the second electrodes 122R, 122G, and 122B on the element formation layer 140. First, the contact hole reaching the source electrode or drain electrode 136b is formed in the interlayer insulating film 137 and the insulating film 139 of the element formation layer 140 and the contact hole reaching the common wiring 138 is formed in the insulating layer 139. Next, an oxide conductive film having light transmittance is formed on the element formation layer 140 (the insulating film 139), and the first electrode 121 and the second electrode 122 are formed by a photolithography process. As a result, the first electrode 121 and the source electrode or drain electrode 136b are electrically connected, and the second electrode 122 and the common wiring 138 are electrically connected. Also, in the present embodiment, although the case where the first electrode 121 and the second electrode 122 are formed in the same process will be described, they may be formed in different processes if the first electrode 121 and the second electrode 122 are formed of different conductive materials.

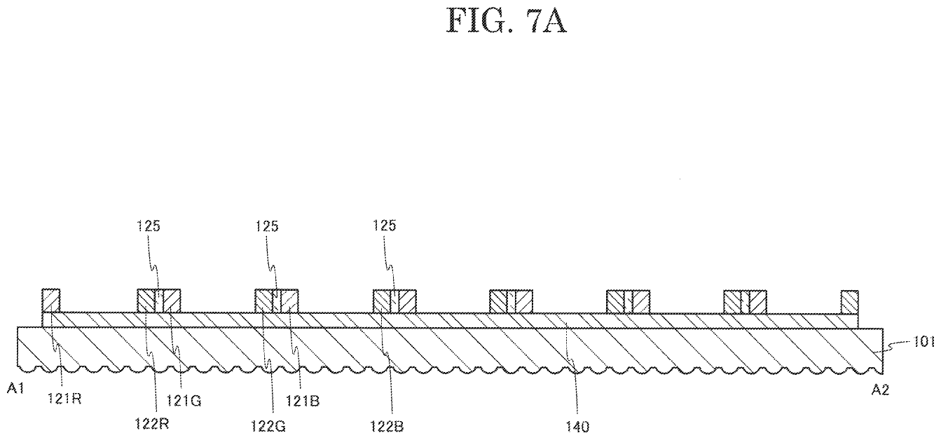

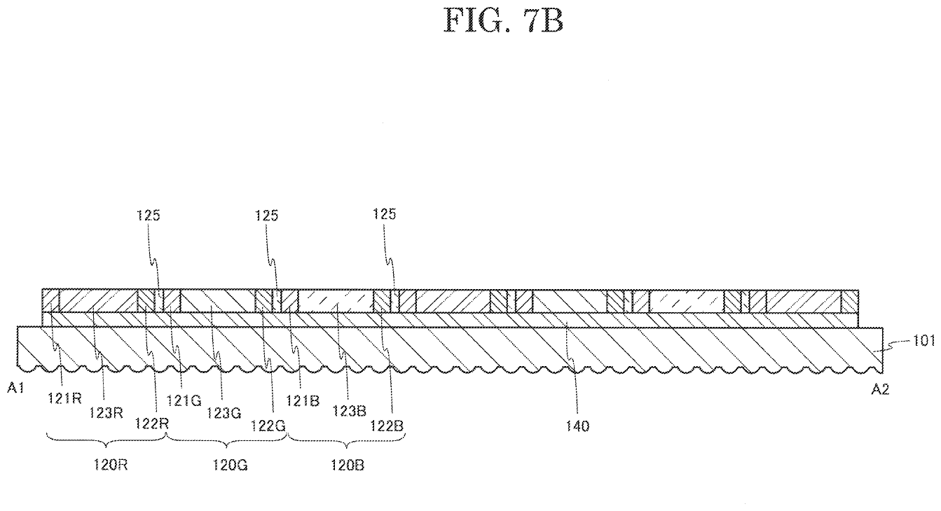

FIG. 7A is a diagram illustrating the process of forming the insulating layer 125 between the first electrode 121 and the second electrode 122. For example, the insulating layer 125 is provided between the second electrode 122R and the first electrode 121G, and the insulating layer 125 is provided between the second electrode 122G and the first electrode 121B. The insulating layer 125 may be a material having light transmittance. For example, the insulating layer 125 may be formed using an inorganic material such as silicon oxide or silicon nitride, or an organic material such as polyimide, polyamide, acryl, or epoxy. For example, in the case where the insulating layer 125 is formed using an organic material, the insulating layer 125 may be formed by coating using an ink-jet method. In the case where the insulating layer 125 is formed by the ink-jet method, the insulating layer 125 may be selectively formed in an area between the first electrode 121 and the second electrode 122.

FIG. 7B is a diagram illustrating the process of forming the light-emitting layers 123R, 123G, 123B on the element formation layer 140. For example, a light-emitting material that emits red light is applied by the ink-jet method to an area where the side surface of the first electrode 121R and the side surface of the second electrode 122R face each other. A light-emitting material that emits green light is applied by the ink-jet method to an area where the side surface of the first electrode 121G and the side surface of the second electrode 122G face each other. A light-emitting material that emits blue light is applied by the ink-jet method to an area where the side surface of the first electrode 121B and the side surface of the second electrode 122B face each other. Also, it is preferred to apply the insulating layer 125 and the light-emitting material by the ink-jet method because they can be formed at the same time. In addition, the light-emitting layers 123R, 123G, and 123B can be randomly arranged by forming the light-emitting material by the ink-jet method as shown in the layout of FIG. 4.

The light-emitting material includes a light-emitting polymer, an ionic liquid, and an organic solvent. Examples of the light-emitting polymer include various 7-conjugated polymers. Specific examples thereof include paraphenylenevinylene, fluorene, 1,4-phenylene, thiophene, pyrrole, paraphenylene sulfide, benzothiadiazole, biotifin, or a polymer of a derivative obtained by introducing a substituent thereto, or a copolymer containing the same. The type of light-emitting polymer may be changed depending on the light-emitting layers 123R, 123G, and 123B. In addition, the ionic liquid is a substance that is an ionic species and maintains a liquid state at room temperature. Although the examples thereof include a substance using a phosphonium system as a raw material, other raw materials may be used. The ionic liquid and the light-emitting polymer are efficiently mixed and used to ensure a reasonable viscosity in order to apply the organic solvent on the element formation layer 140. For example, at least one selected from a group consisting of toluene, benzene, tetrahydrofuran, carbon disulfide, dimethyl chloride, chlorobenzene, and chloroform is preferred to be used as the organic solvent. In this case, only one of these compounds or only a combination of two or more of these compounds can be used as the organic solvent.

Next, the light-emitting material applied to the element formation layer 140 is annealed. The annealing process is preferred to be performed at a temperature at which the light-emitting material does not deteriorate, for example, 120° C. or lower. The annealing process may be performed in the atmosphere or in a vacuum. The light-emitting layers 123R, 123G, and 123B having the light-emitting polymer and the ionic liquid are formed by evaporating the organic solvent contained in the light-emitting material by annealing.

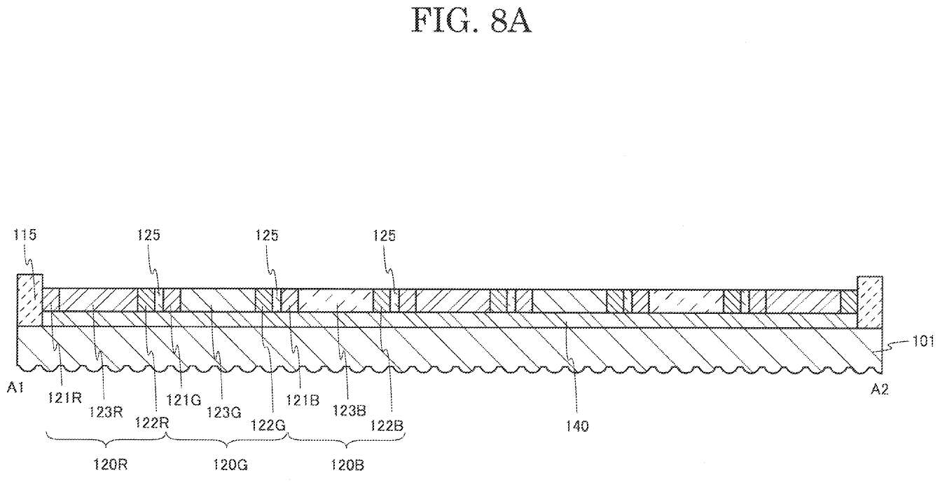

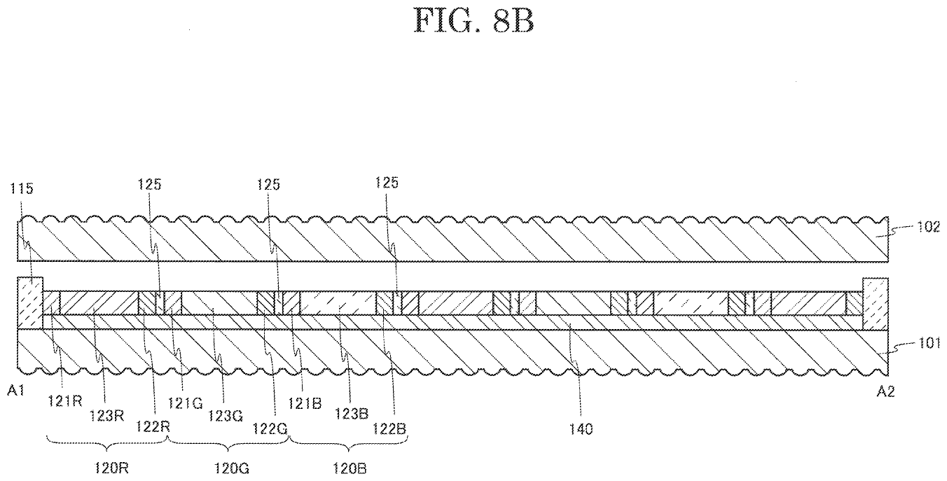

FIG. 8A is a diagram illustrating the process of drawing the adhesive material 115 on the first surface 101a of the first substrate 101. For example, the adhesive material 115 is drawn on the first surface 101a of the first substrate 101 so as to surround the peripheral portion of the first electrode 121 using a light-hardening resin.

FIG. 8B is a diagram illustrating a process of bonding the second substrate 102 on the first substrate 101. The first surface 102a of the second substrate 102 is subjected to the antiglare treatment. In addition, the thickness of the display device 100 can be reduced by setting the thickness of the second substrate 102 to 0.1 mm to 0.3 mm. Also, in the case where a diffuser or a reflector is separately provided on the first surface 102a side, the antiglare treatment may not be performed on the first surface 102a. The bonding of the first substrate 101 and the second substrate 102 may be performed in the atmosphere or in a vacuum. After the first substrate 101 and the second substrate 102 are bonded, the adhesive material 115 is cured by irradiating the adhesive material 115 with light, it is possible to adhere the first substrate 101 and the second substrate 102.

The display device 100 according to one embodiment of the present invention can be manufactured by the above-described processes.

According to the method of manufacturing the conventional light-emitting electrochemical cell, since the light-emitting electrochemical cell is formed by stacking the first electrode, the light-emitting layer, and the second electrode, processes for forming each of them are required.

According to the method of manufacturing the light-emitting electrochemical cell 120 of the present embodiment, the first electrode 121 and the second electrode 122 can be formed on the element formation layer 140 in the same process by forming and processing the oxide conductive film. In addition, even when different light-emitting materials are used, the light-emitting layers 123R, 123G, and 123B can be formed in the same process by applying different light-emitting materials by the ink-jet method. Further, the light-emitting layers 123R, 123G, and 123B, and the insulating layer 125 can be formed in the same process by applying the light-emitting material and the organic material by the ink-jet method. As a result, the manufacturing process of the display device 100 can be simplified.

In the present embodiment, although the case where one display device 100 is manufactured for one substrate, the present invention is not limited thereto. A large substrate can also be used to manufacture a plurality of display devices 100 at once. In this case, a plurality of light-emitting electrochemical cells 120 may be formed on the first substrate 101, and the first substrate 101 and the second substrate 102 are bonded by the adhesive material 115 and then separated for each of the plurality of display devices 100.

### Second Embodiment

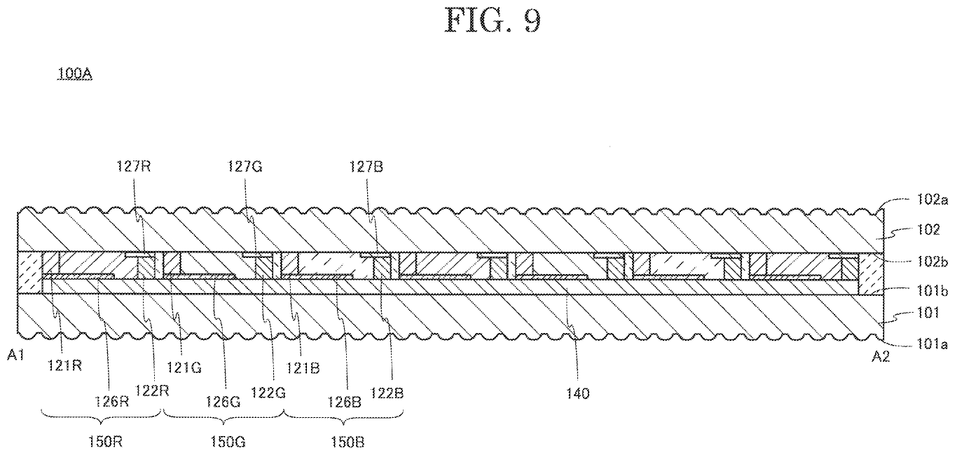

In the present embodiment, a display device 100A having a structure partially different from the display device 100 will be described with reference to FIG. 9 to FIG. 11. FIG. 9 is a cross-sectional view when the display device 100A is cut across a plurality of light-emitting electrochemical cells 150.

The element formation layer 140 is provided on the first surface 101a of the first substrate 101, and the light-emitting electrochemical cell 150 is provided on the element formation layer 140. The light-emitting electrochemical cell 150 includes an auxiliary electrode 126 and an auxiliary electrode 127 in addition to the first electrode 121, the second electrode 122, and the light-emitting layer 123. The auxiliary electrode 126 is provided between the element formation layer 140 and the light-emitting layer 123, and the auxiliary electrode 127 is provided between the second surface 102b and the light-emitting layer 123 of the second substrate 102. The auxiliary electrode 126 is electrically connected to the first electrode 121, and the auxiliary electrode 127 is electrically connected to the second electrode 122. An area in contact with the light-emitting layer 123 can be increased by providing the auxiliary electrode 126.

In addition, the auxiliary electrode 126 and the auxiliary electrode 127 preferably do not overlap each other. This is because a voltage is applied in the thickness direction of the display device 100A by overlapping the auxiliary electrode 126 and the auxiliary electrode 127. In addition, the area where the auxiliary electrode 126 is in contact with the light-emitting layer 123 and the area where the auxiliary electrode 127 is in contact with the light-emitting layer 123 are preferably substantially equal. Brightness unevenness can be suppressed in the light-emitting layer 123 by making the area where the auxiliary electrode 126 contacts the light-emitting layer 123 and the area where the auxiliary electrode 127 contacts the light-emitting layer 123 substantially equal.

The auxiliary electrode 126 and the auxiliary electrode 127 have the oxide conductive layer. For example, ITO and IZO having light transmittance are used as the oxide conductive layer. In addition, an MgAg thin film may be used as the conductive layer having light transmittance instead of the oxide conductive layer. In addition, in the present embodiment, although the hatching of the first electrode 121 and the hatching of the auxiliary electrode 126 are illustrated by different hatching, the first electrode 121 and the auxiliary electrode 126 may be formed of the same conductive material. Similarly, although the hatching of the second electrode 122 and the hatching of the auxiliary electrode 127 are illustrated by different hatching, the second electrode 122 and the auxiliary electrode 127 may be formed of the same conductive material. In addition, the thickness of each of the auxiliary electrode 126 and the auxiliary electrode 127 is preferred to be smaller than the thickness of the first electrode 121 and the second electrode 122. For example, the thicknesses of the auxiliary electrode 126 and the auxiliary electrode 127 are set to be smaller than the thicknesses of the first electrode 121 and the second electrode 122 within a range of 50 nm or more and 150 nm.

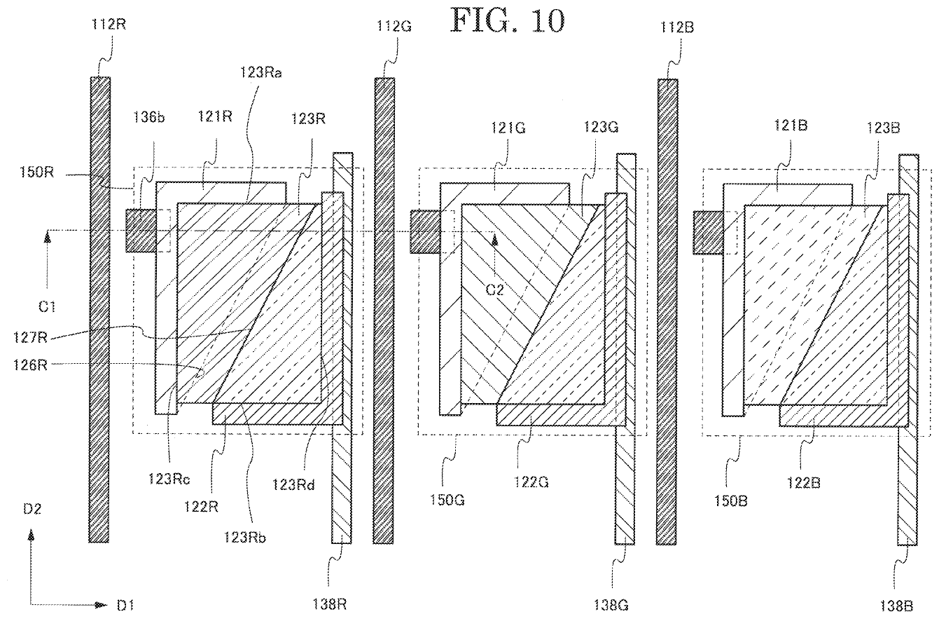

FIG. 10 is a layout of the display device 100A. The layout shown in FIG. 10 is different from the layout shown in FIG. 4 in that the auxiliary electrode 126 and the auxiliary electrode 127 are provided in the first electrode 121 and the second electrode 122.

As shown in FIG. 10, in a light-emitting electrochemical cell 150R, the first electrode 121R has an auxiliary electrode 126R electrically connected to the first electrode 121R, and the second electrode 122R has an auxiliary electrode 127R electrically connected to the second electrode 122R. The shape of the auxiliary electrode 126R is shown by dashed lines because the auxiliary electrode 126R is provided below the light-emitting layer 123R.

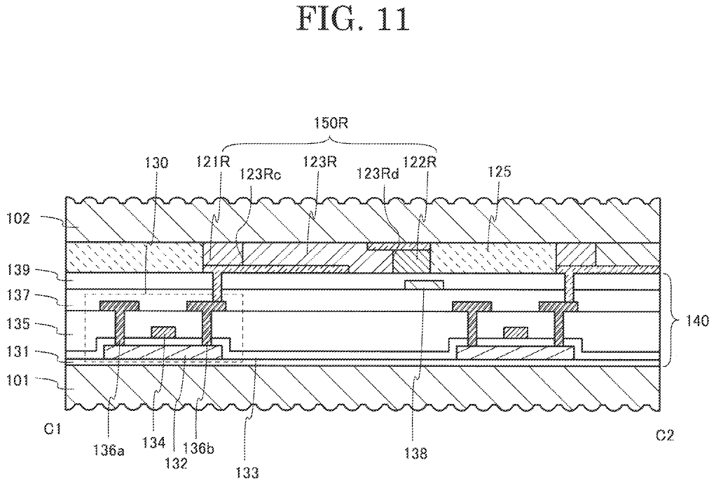

FIG. 11 is a cross-sectional view along a line C1-C2 of the layout of the light-emitting electrochemical cell shown in FIG. 10. A detailed structure of the element formation layer 140 and the light-emitting electrochemical cell 150 will be described in FIG. 11. Also, since a structure of the switching element 130 is the same as that of the switching element 130 shown in FIG. 5, a detailed explanation thereof is omitted.

The interlayer insulating film 137 is provided on the interlayer insulating film 135 and the source electrode or drain electrode 136a, 136b, and the common wiring 138 is provided on the interlayer insulating film 137. The insulating film 139 is provided on the interlayer insulating film 137 and the common wiring 138. An organic insulating film having a planarization function is preferably used as the insulating film 139.

The light-emitting electrochemical cell 150 is provided on the insulating film 139. The auxiliary electrode 126 is provided between the element formation layer 140 and the light-emitting layer 123. The auxiliary electrode 126 is electrically connected to the source electrode or drain electrode 136b via the contact hole formed in the interlayer insulating film 137 and the insulating film 139. The first electrode 121 is provided on the auxiliary electrode 126.

The auxiliary electrode 127 is provided between the second substrate 102 and the light-emitting layer 123. Although not shown in FIG. 11, the second electrode 122 is electrically connected to the common wiring 138 via the contact hole formed in the insulating film 139. The auxiliary electrode 127 is electrically connected to a common wiring 128 via the second electrode 122.

### <Method of Manufacturing Display Device>

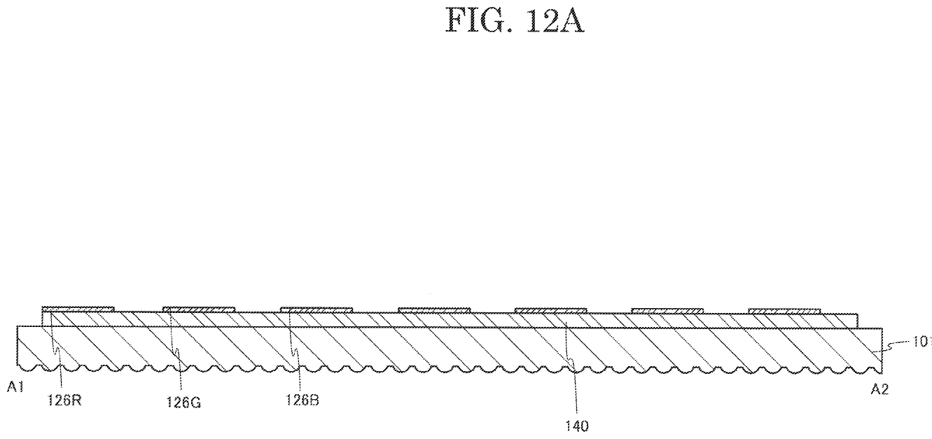

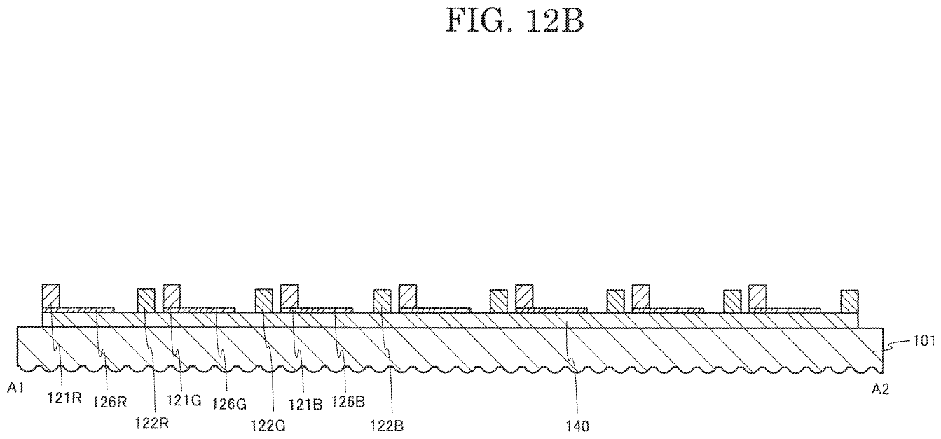

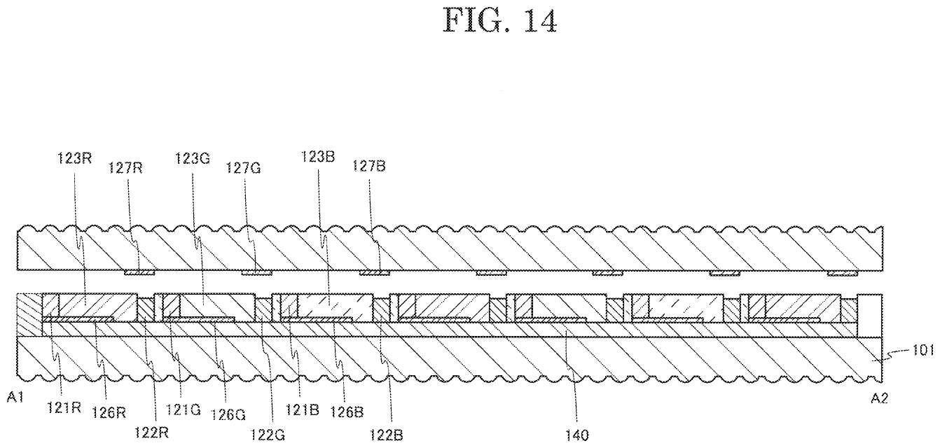

Next, a method of manufacturing the display device 100A according to one embodiment of the present invention will be described while referring to FIG. 12A and FIG. 14.

FIG. 12A is a diagram illustrating the process of forming the element formation layer 140 and the auxiliary electrode 126 on the first substrate 101. The element formation layer 140 is formed on the second surface 101b of the first substrate 101 by a known method. Next, the contact hole reaching the source electrode or drain electrode 136b is formed in the element formation layer 140 and the insulating film 139. In addition, the contact hole reaching the common wiring 138 is formed in the insulating film 139. Next, an oxide conductive film is formed on the element formation layer 140 (the insulating film 139), and the auxiliary electrode 126 is formed by the photolithography process. As a result, the auxiliary electrode 126 and the source electrode or drain electrode 136b are electrically connected.

FIG. 12B is a diagram illustrating the process of forming the first electrode 121 and the second electrode 122 on the element formation layer 140. First, a metal conductive film is formed on the element formation layer 140 (the insulating film 139), and the first electrode 121 and the second electrode 122 are formed by the photolithography process. As a result, the first electrode 121 is provided on the auxiliary electrode 126. In addition, the second electrode 122 is electrically connected to the common wiring 138 via the contact hole formed in the insulating film 139. Also, in the present embodiment, although an example in which the second electrode 122 is directly connected to the common wiring 138 is shown, one embodiment of the present invention is not limited thereto. For example, the second electrode 122 may be connected to the common wiring 138 via a conductive layer made of the same conductive material as the auxiliary electrode 126. It is preferred to use the oxide conductive film as the auxiliary electrode 126 and the metal conductive film as the first electrode 121 and the second electrode 122 because the processing of the auxiliary electrode 126 and the first electrode 121 is facilitated.

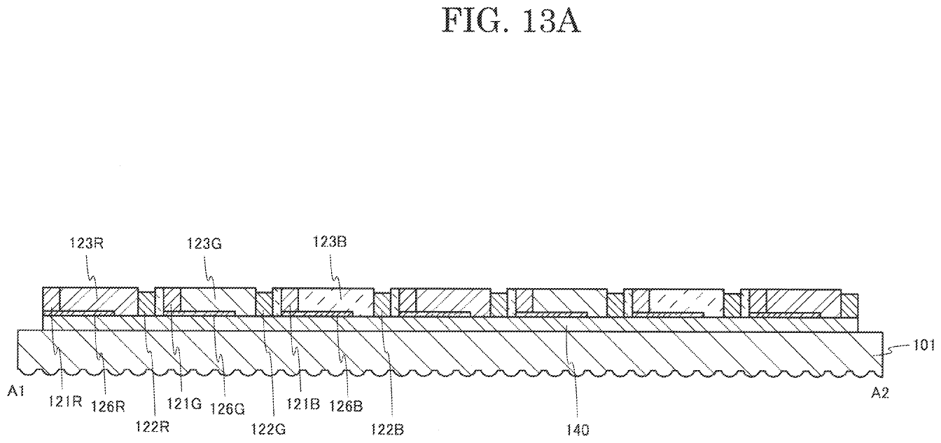

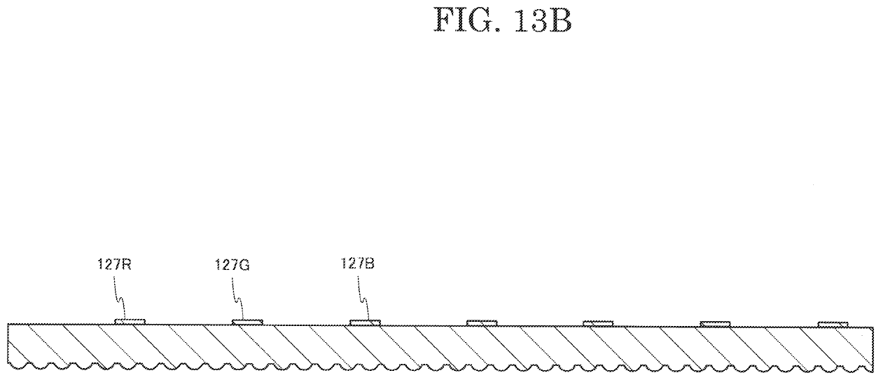

FIG. 13A is a diagram illustrating the process of forming the insulating layer 125 and the light-emitting layers 123R, 123G, and 123B. The insulating layer 125 is formed between the first electrode 121 and the second electrode 122. Next, the light-emitting material that emits red light is applied by the ink-jet method to the area where the side surface of the first electrode 121R and the side surface of the second electrode 122R face each other. The light-emitting material that emits green light by the ink-jet method to the area where the side surface of the first electrode 121G and the side surface of the second electrode 122G face each other. The light-emitting material that emits blue light is applied by the ink-jet method to the area where the side surface of the first electrode 121B and the side surface of the second electrode 122B face each other. It is preferred to apply the insulating layer 125 and the light-emitting material by the ink-jet method because they can be formed at the same time.

Next, the light-emitting material applied to the element formation layer 140 is annealed. The annealing temperature is preferably a temperature at which the light-emitting material does not deteriorate, for example, 120° C. or lower. The annealing atmosphere may be air or vacuum. The light-emitting layers 123R, 123G, and 123B having the light-emitting polymer and the ionic liquid are formed by evaporating the organic solvent contained in the light-emitting material by annealing.

FIG. 13B is a diagram illustrating the process of forming the auxiliary electrode 127 on the second surface 102b of the second substrate 102. An oxide conductive film is formed on the second surface 102b of the second substrate 102, and the auxiliary electrode 127 is formed by the photolithography process.

FIG. 14 is a diagram illustrating the process of bonding the second substrate 102 on the first substrate 101. The first substrate 101 and the second substrate 102 are bonded so that each of the auxiliary electrodes 127R, 127G, and 127B formed on the second surface 102b of the second substrate 102 contacts each of the second electrodes 122R, 122G and 122B. As a result, the first substrate 101 and the second substrate 102 can be bonded so that each of the auxiliary electrodes 122R, 122G and 1228 is in contact with each of the auxiliary electrodes 127R, 127G, and 127B. The bonding of the first substrate 101 and the second substrate 102 may be performed in the atmosphere or in a vacuum. After the first substrate 101 and the second substrate 102 are bonded, the adhesive material 115 is cured by irradiating the adhesive material 115 with light, and it is possible to adhere the first substrate 101 and the second substrate 102.

The display device 100A according to one embodiment of the present invention can be manufactured by the above-described processes.

### (Modification)

Although the display device according to one embodiment of the present invention is described above, the above-described embodiments can be combined with or replaced with each other. In addition, in each of the above-described embodiments, at least some of them can be modified as follows.

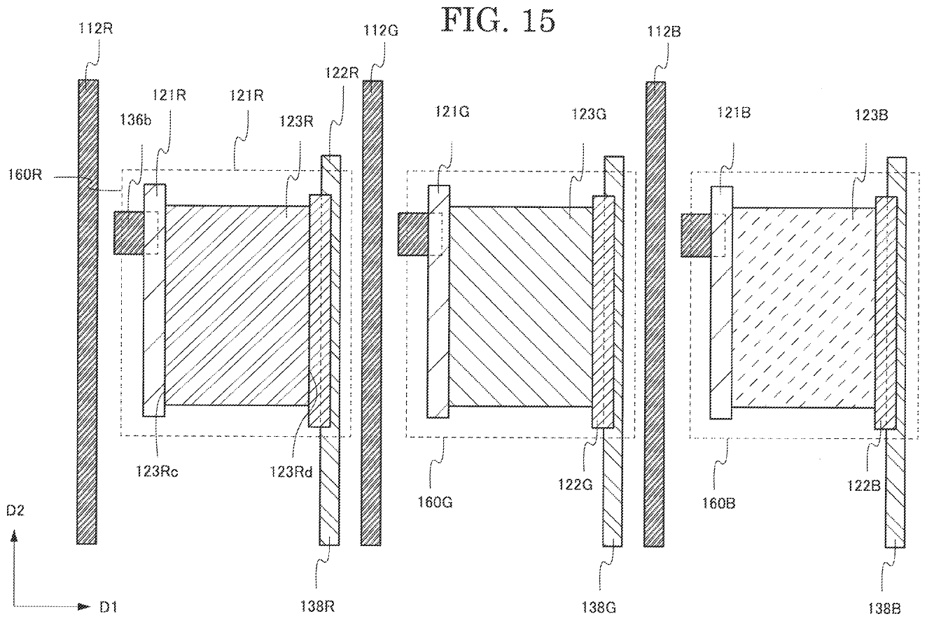

(1) In the first embodiment, although the structure in which the first electrode 121 and the second electrode 122 have the straight portions extending in the first direction D1 and the straight portions bent in the second direction D2 intersecting the first direction D1 is described, the shape of the first electrode 121 and the second electrode 122 is not limited thereto. The first electrode 121 and the second electrode 122 may have at least the straight portion extending in the first direction D1 or the straight portion extending in the second direction D2. FIG. 15 is a diagram in which the first electrode 121 has the straight portion extending in the second direction D2 and the second electrode 122 has the straight portion extending in the second direction D2. The side surface 123Rc of the light-emitting layer 123R is in contact with the first electrode 121R, and the side surface 123Rd is in contact with the second electrode 122R. The light-emitting layer 123R can be made to emit light by applying a voltage between the first electrode 121 and the second electrode 122. Although not shown, the first electrode 121 has the straight portion extending in the first direction D1, and the second electrode 122 has the straight portion extending in the first direction D1. The side surface 123Ra of the light-emitting layer 123R is in contact with the first electrode 121R, and the side surface 123Rb may cause the light-emitting layer 123R to emit light by the side surface 123Rb in contact with the second electrode 122R and by being applied with a voltage between the first electrode 121 and the second electrode 122.

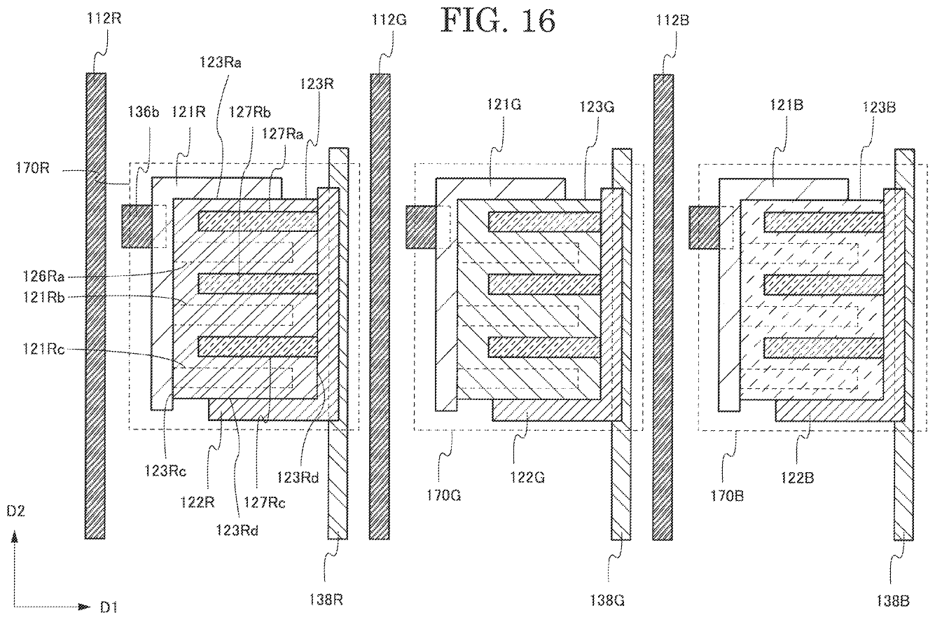

(2) In the second embodiment, although the structure in which the shape of the auxiliary electrode 126 and the auxiliary electrode 127 is provided as a triangle is described, the shape of the auxiliary electrode 126 and the auxiliary electrode 127 is not limited thereto. The auxiliary electrode 126 may have a plurality of areas extending in the first direction D1, and the auxiliary electrode 127 may have a plurality of areas extending in the first direction D1. FIG. 16 is a diagram in which the auxiliary electrode 126 has a plurality of areas 126Ra, 126Rb, and 126Rc extending in the first direction D1, and the auxiliary electrode 127 has a plurality of areas 127Ra, 127Rb, and 127Rc extending in the first direction D1. The plurality of areas 126Ra, 126Rb, and 126Rc may be electrically connected to the first electrodes 121. Therefore, the plurality of areas 126Ra, 126Rb, and 126Rc may be separated or connected. Similarly, the plurality of areas 127Ra, 127Rb, and 127Rc may be electrically connected to the second electrodes 122. Therefore, the plurality of areas 127Ra, 127Rb, and 127Rc may be separated or connected.

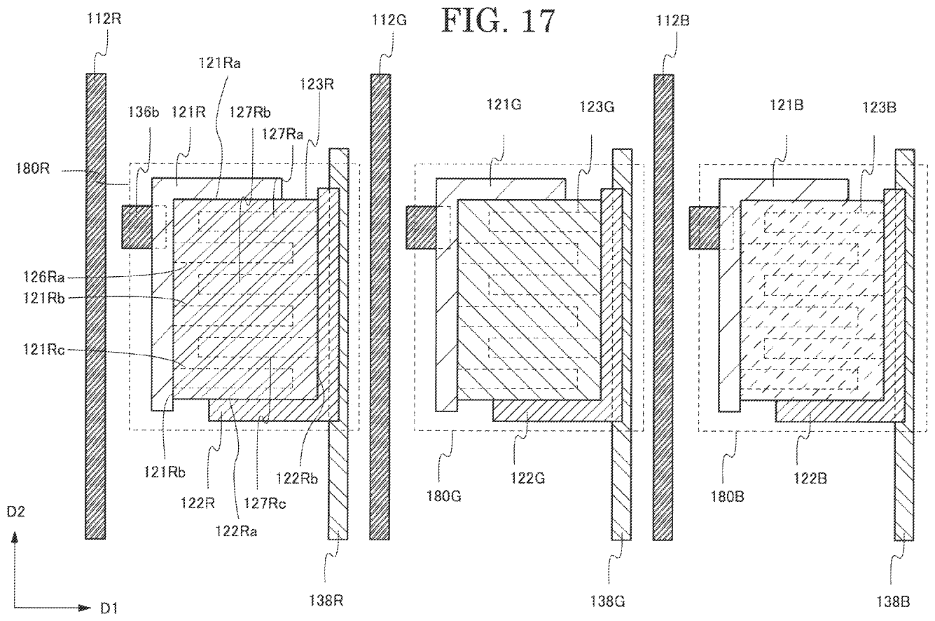

(3) In the second embodiment, although the structure in which the auxiliary electrode 127 is provided between the second surface 102b of the second substrate 102 and the light-emitting layer 123 is described, the position at which the auxiliary electrode 127 is arranged is not limited thereto. Similar to the auxiliary electrode 126, the auxiliary electrode 127 may be provided between the element formation layer 140 and the light-emitting layer 123. FIG. 17 is a light-emitting electrochemical cell partially different from the light-emitting electrochemical cell shown in FIG. 16. FIG. 17 is different from FIG. 16 in that the plurality of areas 127Ra, 127Rb, and 127Rc of the auxiliary electrode 127 is provided between the element formation layer 140 and the light-emitting layer 123. The plurality of areas 127Ra, 127Rb, and 127Rc of the auxiliary electrode 127 can be formed in the same process as the plurality of areas 126Ra, 126Rb, 126Rc of the auxiliary electrode 126 by providing the plurality of areas 127Ra, 127Rb, and 127Rc of the auxiliary electrode 127 between the element formation layer 140 and the light-emitting layer 123R. Although not shown, the plurality of areas 126Ra, 126Rb, and 126Rc of the auxiliary electrode 126 and the plurality of areas 127Ra, 127Rb, and 127Rc of the auxiliary electrode 127 may be provided between the second surface 102b of the second substrate 102 and the light-emitting layer 123.

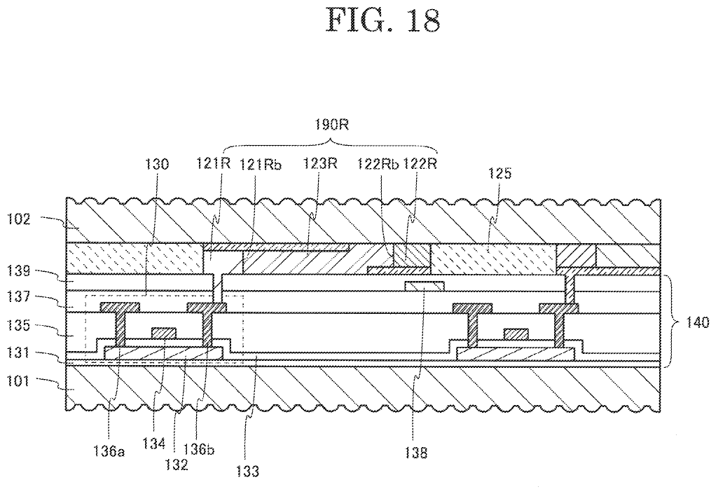

(4) In the second embodiment, although the structure in which the auxiliary electrode 126 is provided between the element formation layer 140 and the light-emitting layer 123, and the auxiliary electrode 127 is provided between the second surface 102b of the second substrate 102 and the light-emitting layer 123 is described, the position where the auxiliary electrode 126 and the auxiliary electrode 127 are arranged is not limited thereto. The auxiliary electrode 126 may be provided between the second surface 102b of the second substrate 102 and the light-emitting layer 123, and the auxiliary electrode 127 may be provided between the element formation layer 140 and the light-emitting layer 123. FIG. 18 shows a light-emitting electrochemical cell partially different from the light-emitting electrochemical cell shown in FIG. 11. In FIG. 18, the auxiliary electrode 126 is provided between the second surface 102b of the second substrate 102 and the light-emitting layer 123R, and the auxiliary electrode 127 is provided between the element formation layer 140 and the light-emitting layer 123R. Although not shown in FIG. 18, the auxiliary electrode 127 is connected to the common wiring 138 via the contact hole formed in the insulating film 139.

Within the scope of the present invention, it is understood that various modifications and changes can be made by those skilled in the art and that these modifications and changes also fall within the scope of the present invention. For example, the addition, deletion, or design change of components, or the addition, deletion, or condition change of processes as appropriate by those skilled in the art based on each embodiment are also included in the scope of the present invention as long as they are provided with the gist of the present invention.

What is claimed is:

1. A display device comprising:
a first substrate having a first surface and a second surface opposite to the first surface;
a first light-emitting layer including a first polymer and an ionic liquid on the second surface;
a first electrode provided on a first side surface of the first light-emitting layer;
a second electrode provided on a second side surface of the first light-emitting layer opposite to the first side surface of the first light-emitting layer; and
a second substrate in contact with the first light-emitting layer and opposite to the first substrate.

2. The display device according to claim 1, wherein
the first electrode is in contact with a third surface adjacent to the first side surface of the first light-emitting layer, and
the second electrode is in contact with a fourth surface adjacent to the second side surface of the first light-emitting layer.

3. The display device according to claim 1, further comprising:
a first insulating layer between the first substrate and the first light-emitting layer; and
a switching element between the first substrate and the first insulating layer,
wherein the switching element is electrically connected to the first electrode.

4. The display device according to claim 3, further comprising:
a first auxiliary electrode electrically connected to the first electrode; and
a second auxiliary electrode electrically connected to the second electrode.

5. The display device according to claim 4, wherein
the first auxiliary electrode is provided between the first insulating layer and the first light-emitting layer, and
the second auxiliary electrode is provided between the first light-emitting layer and the second substrate.

6. The display device according to claim 4, wherein
the first auxiliary electrode and the second auxiliary electrode are provided between the first insulating layer and the first light-emitting layer.

7. The display device according to claim 4, wherein
the first auxiliary electrode is provided between the first light-emitting layer and the second substrate; and
the second auxiliary electrode is provided between the first insulating layer and the first light-emitting layer.

8. The display device according to claim 4, wherein
the first auxiliary electrode does not overlap the second auxiliary electrode.

9. The display device according to claim 4, wherein
the first auxiliary electrode has a first region and a second region extending in a first direction, and
the second auxiliary electrode has a third region and a fourth region extending in the first direction.

10. The display device according to claim 4, wherein
a thickness of the first auxiliary electrode is thinner than a thickness of the first electrode, and
a thickness of the second auxiliary electrode is thinner than a thickness of the first electrode.

11. The display device according to claim 1, further comprising:
a second light-emitting layer containing a second light-emitting polymer and an ionic liquid and provided adjacent to the first light-emitting layer on the second surface of the first substrate;
a third electrode provided in contact with a first side surface of the second light-emitting layer; and
a fourth electrode provided in contact with a second side surface of the second light-emitting layer opposite to the first side surface of the second light-emitting layer,
wherein a peak of an emission spectrum of the first light-emitting layer is different from a peak of an emission spectrum of the second light-emitting layer.

12. The display device according to claim 11, wherein
the third electrode is in contact with a fifth surface adjacent to the first side surface of the second emitting layer, and
the fourth electrode is adjacent to the second side surface of the second light-emitting layer and in contact with a sixth surface opposite to the fifth surface.

13. The display device according to claim 11, further comprising;
a second insulating film provided between the second electrode and the third electrode.
